(19) United States
(12) Patent Application Publication
(10) Pub. No.: US 2011/0108092 A1
(43) Pub. Date: May 12, 2011

(54) CONCENTRATOR FOR SOLAR RADIATION

(75) Inventors: Peter Le Lievre, North Sydney (AU); Andrew Tanner, Mosman (AU); Mikal Greaves, Stanmore (AU)

(73) Assignee: CHROMASUN PTY LTD, North Sydney (AU)

(21) Appl. No.: 12/992,495

(22) PCT Filed: Apr. 28, 2009
(86) PCT No.: PCT/AU2009/000529

§ 371 Date: Jan. 28, 2011

(30) Foreign Application Priority Data
May 13, 2008 (AU) 2008902346
Jan. 14, 2009 (AU) 2009900139
Jan. 14, 2009 (AU) 2009900140
Jan. 14, 2009 (AU) 2009900142
Jan. 14, 2009 (AU) 2009900143
Jan. 14, 2009 (AU) 2009900144
Jan. 14, 2009 (AU) 2009900145

(51) Int. Cl. F24J 2/14; F24J 2/04; H01L 31/052; F24J 2/38; F24J 2/40

(52) U.S. Cl. 136/246; 126/692; 126/634; 126/605; 126/595

(57) ABSTRACT

A concentrator for solar radiation and which comprises a housing having an aperture arranged to admit incident solar radiation and linearly extending receivers located within the housing. A plurality of linearly extending line focusing, tensile-loaded reflector elements is associated with each receiver and arranged to reflect toward the receiver incident solar radiation that enters the housing, and a drive mechanism is located within the housing and arranged to impart sun tracking pivotal drive to the reflector elements. A housing configuration is disclosed that, with aperture-defining windows, provides for maximal admission of solar radiation.

### FIELD OF THE INVENTION

This invention relates to a concentrator for use in the concentration of solar radiation. The invention has application to concentrated irradiation of various possible types of receivers, including those that are arranged to provide for solar-to-thermal, solar-to-chemical and solar-to-electrical energy conversion.

### BACKGROUND OF THE INVENTION

Concentrators of the type with which the present invention is concerned (sometimes referred to as flat panel concentrators) typically are employed in roof-top and similar such applications and, for that purpose, are constructed as relatively unobtrusive units that provide for integrated concentration and collection of incident solar energy.

Various evolutionary types of flat panel concentrators have been developed to incorporate, alternatively, lensing systems and linear trough-type reflector systems, some of which have embodied static collector systems and others of which have incorporated dynamic (sun tracking) collector systems. Specific designs have been developed to provide for solar-to-thermal energy conversion, usually involving the heating of water or other fluid within conduit-type receivers, and solar-to-electrical energy conversion, in this latter case using high performance photovoltaic (PV) cells.

Typical of flat panel concentrators that have background relevance to the present invention is one that is disclosed in WIPO International Publication No. 2007/084517 pursuant to International Patent Application No. PCT/US2007/001159 lodged in the name of Practical Instruments, Inc. as assignee of Hines et al. The disclosed solar concentrating panel comprises a plurality of parallel spaced-apart, trough-like, linear concentrator modules, each of which carries a linear array of PV cells. The concentrator modules have trough walls that are profiled to reflect incident solar radiation toward the PV cells, and the concentrator modules are arranged to be driven to pivot, relative to a support structure, to track apparent movement of the sun. Thus, in the disclosed solar concentrating panel, and in all other linear flat panel concentrators of which the present Applicant is aware, each receiver (for example in the form of a fluid conduit or a linear array of PV cells) is carried by and is thereby associated with a single refractor or a single reflector in the form of a trough-like concentrator module.

Also, large scale linear Fresnel solar-thermal collector systems have been described and constructed for utility-related applications and in which plural (ground-mounted) pivotal reflectors are employed to effect irradiation of elevated linearly extending receivers. However, such systems are different in kind from concentrators of the type with which the present invention is concerned.

### SUMMARY OF THE PRESENT INVENTION

Broadly defined, the present invention provides a concentrator for solar radiation and which comprises: a housing having an aperture arranged to admit incident solar radiation, at least one linearly extending receiver located within the housing, and a plurality of linearly extending line focusing reflector elements associated with the receiver and arranged to reflect toward the receiver incident solar radiation that enters the housing. A drive mechanism is provided to impart pivotal, solar tracking drive to the reflector elements, and at least one window that is substantially transparent to solar radiation defines the aperture of the housing.

The Concentrator desirably incorporates a plurality of receivers and the invention in one of its embodiments may thus be defined as providing a concentrator for solar radiation comprising: a housing having an aperture arranged to admit incident solar radiation, a plurality of laterally spaced linearly extending receivers located within the housing, and a plurality of linearly extending, line focusing reflector elements associated with respective ones of the receivers and arranged to reflect toward the respective receivers incident solar radiation that enters the housing. A drive mechanism is provided to impart pivotal, solar tracking drive to the reflector elements, and at least one window that is substantially transparent to solar radiation defines the aperture of the housing.

With the concentrator components located (wholly) within the covered (i.e., windowed) housing, the various components are (in contrast with the abovementioned large scale linear Fresnel solar-thermal collector systems) protected from wind and other adverse weather conditions. This obviates, or at least reduces, the need for cleaning of the components and facilitates the employment of light weight (low inertia) reflector elements.

The receivers may optionally take various forms, depending upon the form of energy to be output from the concentrator. When, for example, solar-to-thermal energy conversion is required, the receivers will take the form of conduits through which oil, water or other heat exchange fluid may in operation be passed. In this case the conduits may optionally be coated with a solar selective surface coating to enhance the absorption of solar radiation and/or to reduce the emittance of IR radiation.

When solar-to-electrical energy conversion is required, the receivers may each comprise a linear array of PV cells, for example in the form of PV wafer dice secured to a linearly extending carrier.

As indicated above, the solar concentrator may optionally incorporate any desired number of receivers, depending upon output power requirements. However, in one embodiment of the invention the concentrator comprises two receivers, each of which may have an illuminated (target) width of the order of 15 to 40 mm and a length within the range 1000 mm to 4500 mm. Receivers carrying PV wafer dice may typically have a target width of the order of 25 mm and in the case of a solar-thermal embodiment the receivers might typically have a target width of the order of 35 mm.

Each reflector element may comprise a thermally stable moulded or fabricated component having a reflective concentrating surface. However, each reflector element in accordance with one embodiment of the invention desirably comprises a tensile-loaded reflective metal element having a transverse concentrating profile. In this embodiment opposite ends of each reflector element may be connected to support structures of or within the housing by way of coupling members through which pivotal drive may be imparted to the reflector element from the drive mechanism. The tensile loading may be applied to each of the reflector elements by way of the associated coupling members. The loading level will be dependent in part upon the cross-sectional area of a given reflector element but it might typically be within the range 20 kg to 60 kg and most typically comprise a loading sufficient to establish a tensile force in the reflector element of the order of 500N.

With the reflector elements loaded in tension between the end coupling members, each reflector element will effectively be supported in a manner such that its transverse concentrating profile will be preserved along the longitudinal extent of the reflector element.

Each reflector element may optionally comprise a laminated metal structure having an elongate reflector component, an elongate backing component and spacer elements arranged to impart the transverse concentrating profile to the reflector component. However, each reflector element desirably comprises a single-layer metal element that is roll-formed or press-formed with the required transverse concentrating profile, for example, a part circular or parabolic profile.

Each reflector element may optionally be formed in part or in whole from any reflective metal and may, for example, be formed from sheet or strip aluminium having a silvered or anodised reflective surface. Such reflector element may have a thickness within the range 0.05 to 2.0 mm. The dimension (e.g., radius of curvature) of the concentrating profile will be dependent on the distance between a given reflector element and its associated receiver within the concentrator unit.

The longitudinally spaced coupling members that connect opposite ends of each reflector element to the support structure may be mounted for rotation to end walls of or comprising the support structures. Also, in one embodiment of the invention the coupling members associated with at least one of the end walls are moveable axially with respect to the end wall for the purpose of applying tensile loading to the reflector elements.

Each coupling member may comprise two clamping components arranged to receive and clamp onto an end region of the associated reflector element. Also, the clamping components may be profiled to provide a clamping interface that matches the concentrating profile of the associated reflector element, whereby the profile is maintained between and adjacent the clamping components independently of its pre-formation. With this arrangement, if each reflector element is formed from a flexible metal strip of thickness substantially less than 0.3 mm and/or if the reflector element is relatively short (of the order of 1000 mm or less), then it is possible that the transverse concentrating profile may be imposed on the reflector element throughout its longitudinal extent by the coupling members, without there being any requirement for pre-formation of the reflector element.

As an alternative to the reflector element per se being loaded in tension, each reflector element may be carried by a pair of tensile loaded wires. In this case the reflector element may be simply-supported on the pair of wires, or the wires may themselves comprise the above mentioned spacer elements of a laminated reflector element structure.

In the context of the reflector elements, the Applicant has determined from studies made of radius sensitivity plots applicable to reflector elements having a circular concentrating profile, that a deterioration occurs in the optical performance of reflector elements with changes in the radius of curvature greater than or less than an optimum radius of curvature. It has also been determined that the wider a reflector is (i.e., the greater the chord width), the more precise the radius of curvature must be in order to minimise the affects of an aberration akin to astigmatism. On the other hand, the closer a given reflector element is to its associated receiver, the less significant will be the affects of that aberration and, hence, the less precise the radius of curvature will need be. As a further significant factor, as the distance of a given reflector element from its associated receiver increases, so the curvature should decrease (i.e., the radius of curvature should increase), giving rise to a potential increase in astigmatic-like affects. The present invention in one of its aspects seeks to accommodate these various factors, some of which are mutually conflicting, and, thus, in one embodiment of the invention the respective reflector elements associated with a given receiver may be formed with a radius of curvature that increases and a chordal width that decreases with increasing distance of the reflector elements from the receiver.

In the case of a solar-thermal embodiment of the concentrator, in which the receiver target width may be relatively large; five to ten reflector elements may, for example, be provided per receiver, all reflector elements having a common chord width within the range 60 mm to 75 mm and a common radius of curvature within the range 600 mm to 900 mm, depending upon the dimensions of the concentrator housing. In the case of a solar-PV embodiment of the concentrator, a larger number of reflector elements (for example, ten to twelve) may be provided per receiver, with the reflector elements having a chord width that decreases, for example from about 60 mm to about 35 mm, with distance from the associated receiver and a curvature radius that increases with distance from the associated receiver.

Various factors in the operation of the concentrator as above defined may result in the movement off-target of radiation that is intended to be reflected from the reflector elements to associated ones of the receivers. For example, a loss of synchronisation between the reflector drive and the changing angle of incident radiation may contribute to off-target movement of reflected radiation, as may end-to-end twisting of the reflector elements, and a system may in accordance with one embodiment of the concentrator be employed to correct for such tracking problems.

Thus, the concentrator may incorporate a reflector tracking system that is arranged to detect for off-target movement of reflected radiation and to effect on-target restoration drive control of the reflector drive mechanism. This system may take various forms and comprise, for example, photo-detector devices positioned, in the case of a multi-receiver concentrator, adjacent first and second edges respectively of at least one of the receivers, and a controller connected between the photo-detector devices and the reflector drive mechanism. In this embodiment of the concentrator, the controller will be arranged to detect a signal from the first or second photo-detector device, signifying movement of reflected radiation off-target from the receiver and, consequently, to provide an on-target restoration signal to the reflector drive mechanism. Alternatively, in the case of a solar-thermal concentrator, a temperature sensor may be employed to monitor the temperature of the receiver(s) or of heat exchange fluid flowing through the receiver(s), with an associated controller being arranged to provide feedback control of the reflector drive mechanism as determined to maintain a predetermined (typically maximum) temperature level at the receiver. The temperature monitoring may be done adjacent each end of each receiver and, in so doing, detection may be made for end-to-end twisting of an associated reflector element.

In the case of a solar-electrical concentrator, on-target control over the reflector drive mechanism may be derived from measurement of output power from the PV array. Off-target movement of reflected radiation will be indicated by a drop in output power from a predetermined level, with a control system providing feedback control of the reflector drive mechanism to establish on-target irradiation of the receiver(s) and maintenance of the predetermined output power level.

In the case of a concentrator having two receivers, four reflector drive mechanisms may optionally be incorporated in the concentrator, one at each end of the reflector elements associated with each receiver. Then, in the event that end-to-end twisting of a reflector element is detected, compensating adjustment may be made to one of the drive mechanisms. For this purpose a single controller may be employed for the two drive mechanisms that are associated with each group of reflector elements or separate controllers may be employed for the respective drive mechanisms.

A secondary reflector may be positioned adjacent each of the receivers and may be configured to provide one or another (or all) of the following functions:

1. Maximise the area of receiver illumination.
2. Obviate or minimise the requirement for insulation at the dark side of the receiver.
3. Increase the capture area of illuminating radiation.

Thus, a secondary reflector element may be positioned adjacent the or, if more than one, each of the receivers and be profiled or otherwise arranged to reflect to the associated receiver off-target radiation that impinges on the secondary reflector.

Also, the concentrating profile of the (primary) reflector elements may be selected in a manner to cause the reflected radiation to be defocused adjacent the secondary reflector, to improve the uniformity of flux distribution of radiation impinging on the receiver.

In one embodiment of the concentrator, the housing comprises a cover portion in which three windows may be provided to define the aperture of the concentrator. Thus, upper and oppositely positioned side windows may be provided within the cover portion, with each of the side windows being inclined to form with the upper window an included angle within the range 105° to 165°. The cover portion is in use fitted to the concentrator unit such that the upper window will admit solar radiation from overhead, with the opposite side windows facing generally in easterly and westerly directions when, as would normally be the case, the concentrator receivers extend generally in a north-south direction.

With the side windows inclined as above defined, maximal admission of solar radiation may be achieved and a four-fold benefit may be achieved over what would otherwise be a more oblong housing cover construction. Shadowing of receivers that are located adjacent the sides of the concentrator housing is minimised, adjacent concentrator units may be positioned more closely without creating shadowing at low sun angles, the structural strength of the cover portion and, hence, the housing as a whole is increased and, at an aesthetic level, greater visual streamlining is achieved.

The two side windows may optionally be inclined to form different included angles with the upper window but both of the side windows desirably are inclined to the same extent and, most desirably, each forms an included angle with the upper window of the order of 150°. Thus, the included angle subtended by the two side windows most desirably is of the order of 120°.

The upper and side windows desirably are formed from glass, although other light transmissive materials may be employed. The glass most desirably is coated with an anti-reflective coating and has a thickness within the range 3 mm to 5 mm.

The receivers may optionally be carried within the cover portion, for example by elements of a skeletal frame of the cover portion.

The solar concentrator will, for optimum performance, typically be mounted to a support structure, for example a building roof, with the receivers and reflectors orientated in a north-south direction, and be inclined (at an angle as determined by the latitude of its geographical location) to face a generally southerly direction if it is located in the northern hemisphere or to face a generally northerly direction if it is located in the southern hemisphere. However, where circumstances so dictate, the concentrator may be mounted horizontally and be sited with the receivers and reflectors orientated in an east-west direction. Wherever and however it may be mounted; with low sun angles shadow banding will occur at one end of the solar concentrator, at the southern end in the case of a solar concentrator sited in the northern hemisphere, at the northern end in the case of one sited in the southern hemisphere, and at both ends in the case of one sited with the reflector elements orientated in the east-west direction.

The shadow banding may be minimised by maximising the window area in the cover portion and/or by minimising the height of end walls of a base portion of the housing. However, it may further be countered in one embodiment of the concentrator by locating a fixed reflector within the housing at a low-angle illuminated end, or both ends, of the housing in a position to reflect to the receiver(s) incident low-angle solar radiation that enters the housing. The fixed reflector functions effectively to increase the quantum of reflected radiation to the receivers at the low-angle illuminated end of the housing and, thus, compensates for shadowing at the other end of the concentrator.

By “low-angle illuminated end” of the housing is herein meant the northern end of the housing when the solar concentrator is orientated north-south and is located in the northern hemisphere, the southern end of the housing when the solar concentrator is orientated north-south and is located in the southern hemisphere, and both the eastern and western ends of the housing in the case of an east-west orientated concentrator. Also, by “low-angle solar radiation” is herein meant solar radiation that occurs with low sun angles (i.e., with low solar elevation) and which, as a consequence, results in shadow banding.

In order to militate further against the abovementioned astigmatism-like aberration, the focal length, f, of each reflector element may be selected to satisfy the relationship f>d, where d=length of the principal axis between a reflector element and the associated receiver. The selection of focal length of the each reflector element to meet the above conditions will be dependent in part upon the profile of the reflector element, for example upon whether the reflector element has a circular or parabolic concentrating profile. In the case of reflector elements having a circular concentrating profile, the focal length of the reflector elements is determined as f=r/2, where r is the radius of curvature of the reflector element, and, thus, the radius of curvature may be increased to satisfy the previously stated relationship f>d. The focal length might be derived, for example, for a given level of concentration, as f=1.05d to f=1.15d.

Pivotal, sun tracking, movement may be imparted to the reflector elements by way of a linear motor-and-slide drive arrangement, and single axis tracking may be controlled in a conventional manner using shadow band detection of the sun angle.

The invention will be more fully understood from the following description of various aspects of an illustrative embodiment of the solar concentrator. The description is provided by way of example and with reference to the accompanying drawings.

### BRIEF DESCRIPTION OF THE DRAWINGS

FIG. 1 shows a perspective view of the complete solar concentrator unit but omits external connections to what might comprise conventional, external heat exchange and/or electrical circuits,

FIG. 2A shows on an enlarged scale a sectional elevation view of part of a cover portion of the concentrator as seen in the direction section plane 2-2, with a “PV” receiver assembly mounted to a skeletal frame element of the cover portion,

FIG. 2B shows a view similar to that of FIG. 2A but with a “thermal” receiver assembly mounted to the skeletal frame element of the cover portion,

FIG. 3 shows a perspective view of the concentrator housing and illustrates the angular relationship of upper and side windows of the cover portion of the housing,

FIG. 4 shows a partly diagrammatic end elevation view of receiver assemblies and reflector elements that are located within the concentrator, as seen in the direction of section plane 4-4 shown in FIG. 1,

FIG. 5 shows a diagrammatic end elevation view of a group of ten reflector elements and an associated receiver, again as seen in the direction of section plane 4-4 shown in FIG. 1,

FIG. 6 shows a perspective view of a portion of an assembly of ten reflector elements, as would be associated with one receiver assembly, and an associated drive mechanism at one end of the reflector elements,

FIG. 7 shows a perspective view of one end of a reflector element and a coupling member removed from an end wall of the assembly shown in FIG. 6,

FIG. 8 provides a schematic representation of a reflector tracking/control system that is suitable for use in the concentrator, and

FIG. 9 shows a side elevation view of a base portion of the concentrator housing and a fixed reflector located within the base portion, the view being taken in the direction of section plane 11-11 shown in FIG. 1.

### DETAILED DESCRIPTION OF EXEMPLARY EMBODIMENT OF THE INVENTION

As illustrated in FIG. 1, the solar concentrator comprises a housing 10 having a base portion 11 and a cover portion 12. The cover portion has a generally rectangular aperture (as viewed from above) which is defined by three windows, an upper window 13 and side windows 14 and 15. The upper and side windows are formed from a material that is transparent to solar radiation, typically glass having a thickness of the order of 3 mm to 5 mm. End panels 16 of the cover portion may also be formed from glass or, alternatively from a translucent or opaque material. The complete housing 10, including the cover portion 12, might typically have dimensions of the order: length (north-south) 2.50 m to 4.5 m, width (east-west) 1.0 m to 3.0 m and height 0.3 m to 0.4 m.

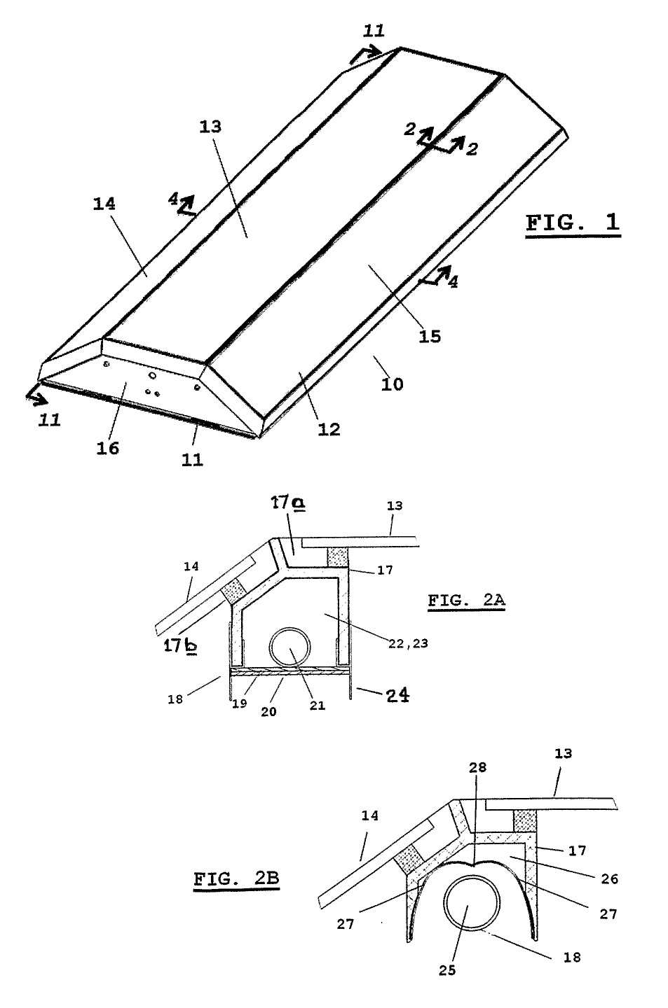

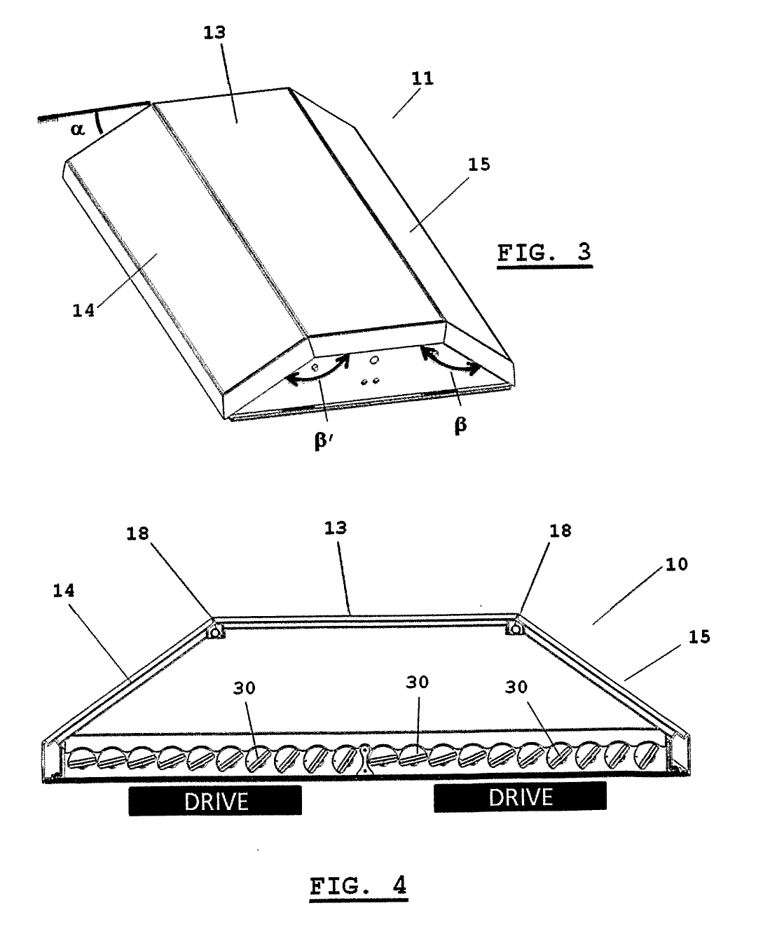

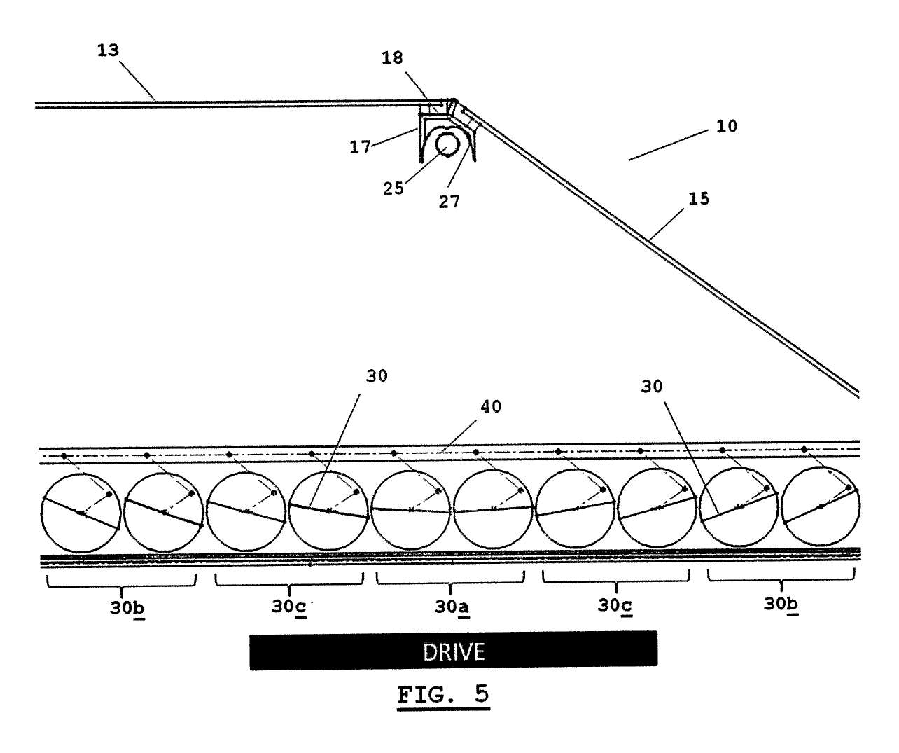

The housing cover 12 comprises a skeletal frame structure 17, a portion only of which is shown in FIGS. 2A and 2B, to which the widows 13 to 15 are secured. The skeletal frame structure 17, which optionally is fabricated from separate metal extrusions, is shaped such that, as shown in FIG. 3, the side windows 14 and 15 are inclined at angle α to the (horizontal) plane of the upper window 13, and each of the side windows is inclined to form with the upper window 13 an included angle δ. The angle δ lies within the range 105° to 165° and most desirably is of the order of 150°. Thus, the angle α lies within the range 15° to 75°, and most desirably is of the order of 30°.

The two side windows 14 and 15 may optionally be inclined to form different included angles δ and δ¹ with the upper window 13. However, the side windows desirably are inclined at the same angle and, thus, the included angle subtended by the two side windows is desirably of the order of 120°.

The housing 10 in use will typically be mounted to a support structure, for example a building roof, to extend lengthwise in a north-south direction.

Two parallel linearly extending receiver assemblies 18 are mounted within the housing and are located adjacent the apices of the upper and respective side windows of the cover portion 12. The receiver assemblies 18 extend linearly in the north-south direction when the concentrator is in situ and they are spaced apart laterally in the east-west direction.

As indicated previously, the receiver assemblies 18 may take different forms for different types of concentrators, depending upon the nature of output. FIG. 2A shows an end view of a receiver assembly that is appropriate to a concentrator that is intended to provide for solar-to-electrical energy conversion, and FIG. 2B shows an end view of a receiver assembly that is appropriate to a concentrator that is intended to provide for solar-to-thermal energy conversion.

As shown in FIG. 2A, the receiver 18 comprises a longitudinally extending elongate substrate 19 on which a plurality of PV wafer dice 20 is arrayed in the longitudinal direction of the substrate. The wafer dice 20 are arranged in use to be exposed to reflected solar radiation, and electrical connections (not shown) are made between the rear side of the dice and busbars that are located on of the substrate 19. A thermally conductive, electrically non-conductive coating material is interposed between the busbars and the substrate 19. Although not so shown, the substrate and wafer dice may be encapsulated in an epoxy resin and be located behind a glass covering.

A PV receiver of a type that is suitable for use in the concentrator of the present invention (and having a linear array of wafer dice) is disclosed in U.S. Provisional Patent Application No. 61/110,109 filed 31 Oct. 2008 by Krauskopf et al and subsequently assigned to the present Applicant.

A metal conduit 21, that is carried within a longitudinally extending channel 22 of a north-south extending portion of the skeletal frame portion 17 of the cover, is mounted in thermal contact to the rear face of the substrate 19. The conduits 21 in the two laterally spaced receiver assemblies 18 are connected in series and, in use, carry a heat exchange fluid (from an external circuit) that is employed to maintain the PV dice at an appropriate operating temperature. Depending upon the type of heat exchange fluid (e.g., oil or water) that is employed in any given application and the operating temperature, the conduit 21 may be formed from copper or black-chrome-plated steel.

The region of the channel 22 that is not occupied by the conduit 21 is filled with an insulating material 23. Also, the space 17a above the channel 22 is occupied by an epoxy resin that is employed to retain the window glass and the epoxy resin is retained whilst setting by a spacer 17b.

Downwardly projecting, longitudinally extending metal side walls 24 form sides of a lower channel of the receiver assembly and function also as a secondary reflector for reflected radiation that would otherwise spill, off-target, to the sides of the PV wafer dice array.

Although the receiver assembly 18 has been described above in the context of solar-to-electrical energy conversion, the same receiver structure, but with the PV wafer dice omitted, may be employed for solar-to-thermal energy conversion, as an alternative to that shown in FIG. 2B.

The receiver assembly 18 as shown in FIG. 2B comprises a metal conduit 25 that is carried within the longitudinally extending channel 22 of the north-south extending portion of the skeletal frame portion 17 of the cover. In this embodiment also, the conduits 25 in the two laterally spaced receiver assemblies 18 are connected in series but, in use, they carry a heat exchange fluid that is to be employed externally in a downstream thermal transfer process. The conduit 25 in each receiver assembly is exposed directly to reflected solar radiation and, in this embodiment also, the conduit 21 may be formed from copper or black-chrome-plated steel, depending upon the type of heat exchange fluid and the operating temperature.

A longitudinally extending channel-like secondary reflector 26 is located within the channel 22 behind the conduit 25 and is employed in use to reflect to the conduit solar radiation that would otherwise spill, off-target, to the sides of the conduit. The secondary reflector in this embodiment is formed geometrically as two part-parabolic portions 27 that interconnect along a central longitudinally extending cusp 28.

As illustrated in FIGS. 4 to 6, a group of ten linearly extending, line focusing reflector elements 30 is associated with and located below each of the two receivers 18 within the concentrator housing 10, and the reflector elements 30 of the two groups are disposed to reflect upwardly, toward the respective receivers 18, incident solar radiation that passes through the transparent top and side windows 13 to 15 of the housing cover 12. Each group of reflector elements 30 may comprise between four and twelve (more typically ten, as illustrated) individual reflector elements 30 which are supported for pivotal (sun tracking) movement in the east-west direction. Four drive mechanisms 31 (as below described) are located within the housing 10, one at each end of each group of reflector elements 30 for imparting pivotal drive to the reflector elements.

Each reflector element 30 has approximately the same length as its associated receiver 18, and each of the reflector elements has a part-circular concentrating profile, although other concentrating profiles, for example parabolic, may also be employed. The concentrating profile may be imposed by a roll-forming or press-forming operation.

In the case of a part-circular concentrating profile, the radius of curvature of the reflector element may be optimised across a group (if the target width is sufficiently large) or, in another embodiment, may be determined by the distance between a given reflector element and its associated receiver; but might typically be of the order of 200 mm to 700 mm.

Each reflector element 30 is formed from sheet or strip aluminium, typically having a thickness of the order of 0.30 mm, and it is provided with a silvered or anodised upper reflective surface. The reflector element may be formed from a material marketed under the Trade Mark Alanod.

Each reflector element 30 will typically have a width within the range 45 mm to 70 mm and, as described below in relation to FIG. 5, in one embodiment of the concentrator both the radius of curvature and chord width of the reflector elements associated with respective receivers 18 may be varied as a function of the distance of the reflector elements from the respective receivers.

FIG. 5 illustrates an arrangement in which ten reflector elements 30 are associated with each receiver 18. The reflector elements that are associated with each receiver assembly have a radius of curvature that increases and a chordal width that decreases with distance of the reflector elements from the receiver assembly. The radius of curvature of the respective reflector elements 30 will in such case will be dependent upon the distance of the reflector elements from the associated receiver assembly 18 and the respective reflector elements may have a chord width which decreases from approximately 60 mm to approximately 35 mm with distance away from the receiver.

Thus, for example, the two central reflector elements 30a may have a chord width of 58 mm, the two outermost reflector elements 30b at each side may have a chord width of 38 mm, and the two groups of two intermediate reflector elements 30c may have a chord width of 48 mm.

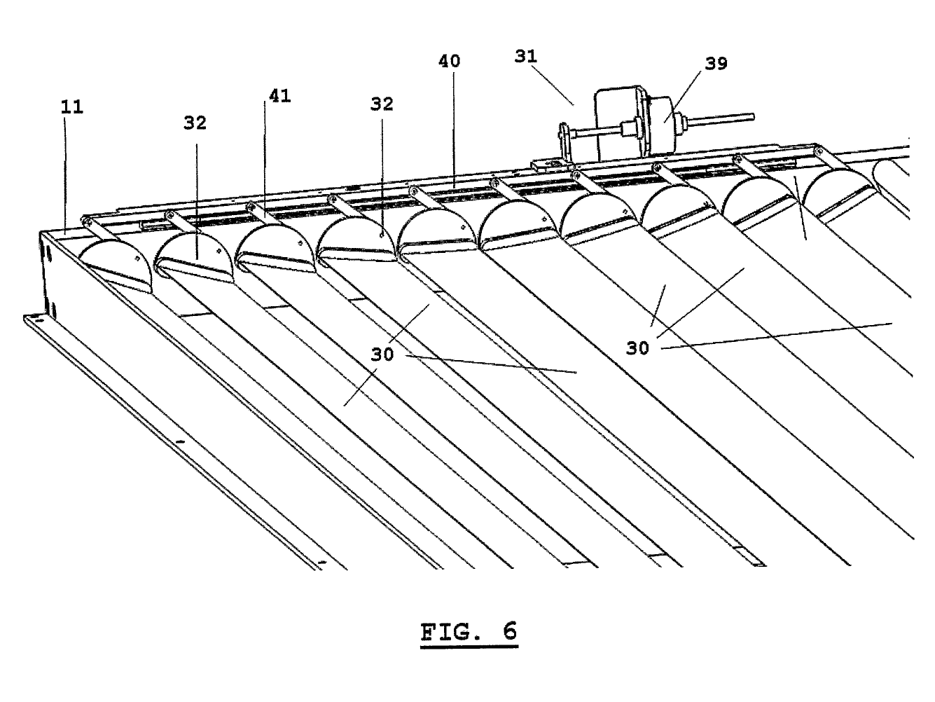

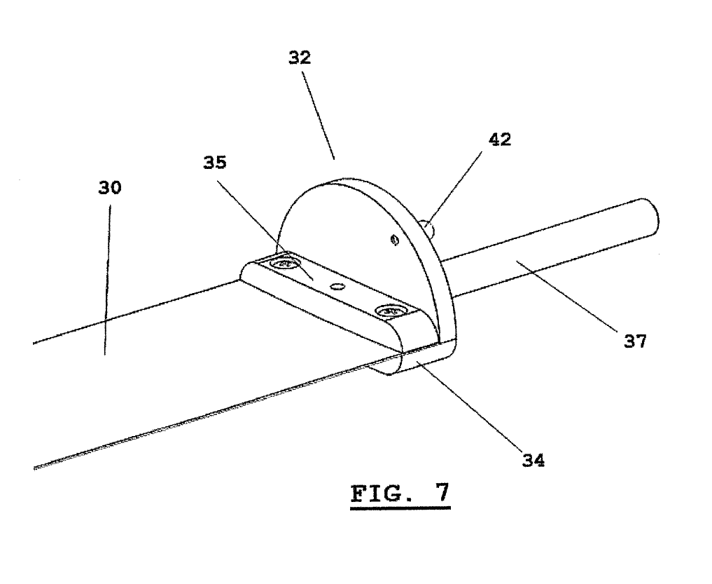

FIG. 6 shows a single group of ten reflector elements 30 (as might be associated with a single receiver 18) and, as illustrated in both FIGS. 6 and 7, each reflector element 30 within the housing 10 extends between longitudinally spaced coupling members 32 which connect opposite ends of each reflector element to fixed end walls 33 within the base portion 11 of the housing 10. The drive mechanisms impart pivotal motion to the reflector elements 30 by way of the coupling members 32, and a tensile load is imposed on each of the reflector elements, again by way of the coupling members.

The reflector elements 30 are loaded in tension to a level within the range 20 kg to 60 kg and, as previously stated, as a consequence of the reflector elements being loaded in tension between the longitudinally spaced coupling members 32, each reflector element is effectively supported in a manner such that its transverse concentrating profile is preserved along the longitudinal extent of the reflector element.

The longitudinally spaced coupling members 32 are mounted for rotation to the respective end walls 33, and each coupling member 32 is moveable axially with respect to the end wall 33 for the purpose of loading the associated reflector element in tension and, as required, adjusting the tensile load.

Each coupling member 32 comprises two clamping components 34 and 35 which are arranged to receive and clamp onto an end region of the associated reflector element 30. Also, the clamping components are profiled to provide a clamping interface 36 that matches the concentrating profile of the associated reflector element. Thus, the profile is maintained between and adjacent the clamping components independently of its pre-formation.

Rotation of the coupling members 32 causes pivotal motion to be imparted to the reflector elements 30, and a stub axle 37 that extends rearwardly of a disc-like portion 38 of the clamping component 34 projects through the end wall 33. The axle 37 of each coupling member 32 is carried in a thrust bearing (not shown) to accommodate the tensile force imposed on the coupling member 32 with tensile loading of the reflector element 30.

Solar tracking pivotal drive is imparted to all of the coupling members 32 at the opposite ends of each group of the reflector elements 30, at the solar (apparent) procession rate of 0.125° per minute, by a linear stepping motor 39 of the drive mechanism 31. Linear output motion from the motor is imparted to a linear slide-type actuator 40, and translational motion of the linear actuator 40 is transferred as rotary motion to all of the coupling members 32 (which are moved in unison) by pivotal links 41. The pivotal links interconnect the linear actuator 40 and the coupling members 32 by way of linkage pins 42 projecting rearwardly of the coupling members.

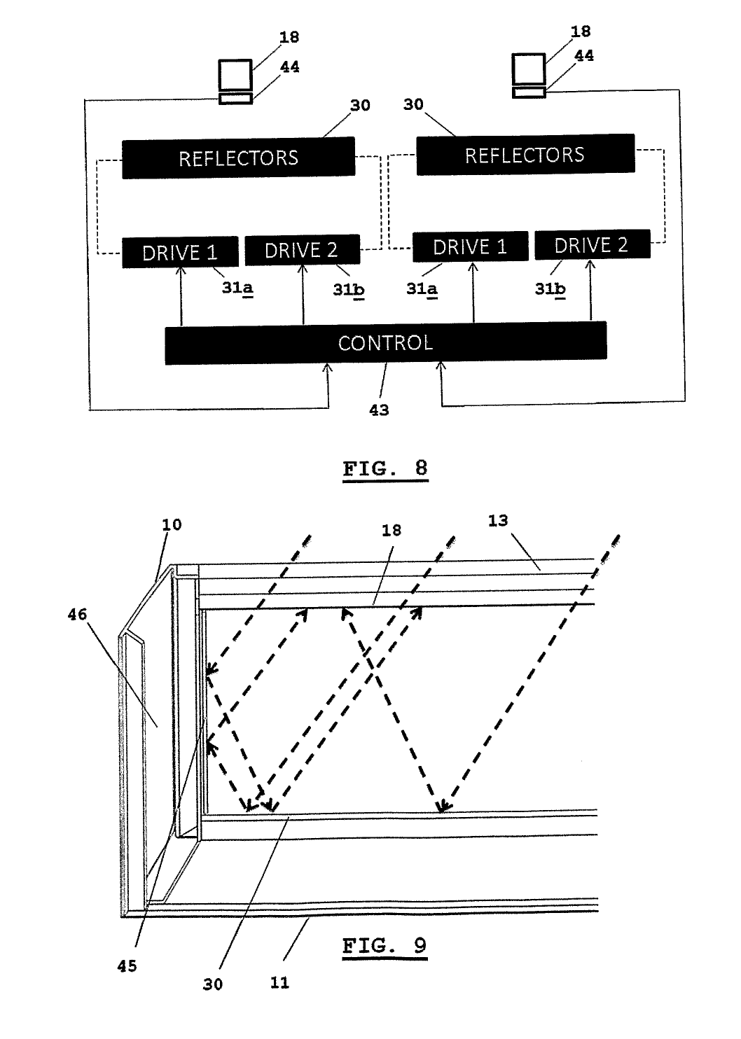

The drive mechanism 31 as shown in FIG. 6 is duplicated at both ends of each group of reflector elements 30, to minimise the risk of torsional twisting of the reflector elements. That is, as shown schematically in FIG. 8, two longitudinally spaced drive mechanisms 31a and 31b are coupled to and act on the group of reflector elements 30 that are associated with each of the receivers 18, and an electrical synchronising system 45 is employed to link each of the two drive mechanisms 31a and 31b.

Temperature sensors 44 (for example in the form of thermocouple devices) are located adjacent (but spaced inwardly from) each end of each of the receivers 18 and are employed to facilitate synchronisation of the drive mechanisms 31a and 31b. The sensors 44 and associated circuitry (not shown) may also be employed to facilitate on-target tracking of the receivers by the reflector elements, by controlling positioning of the reflector elements 30 to maintain a maximum level of temperature at each of the receivers.

Although not shown, sensing circuitry may also be provided to detect for any over-temperature operation and to initiate off-receiver rotation of the reflector elements in the event of an adverse operating condition. Furthermore, electronic switching (not shown) may be provided to effect rotation of the reflector elements off-sun under fault conditions or to permit maintenance operations.

As above mentioned, depending upon the location and orientation of the solar concentrator unit, with low sun angles shadow banding may occur at one or the other or both ends of the solar concentrator 10; for example at the southern end in the case of a solar concentrator sited in the northern hemisphere. The end(s) of the concentrator at which shadow banding does not occur is referred to herein as the “low-angle illuminated end”.

FIG. 9 illustrates a reflector arrangement that provides compensation for shadow banding and in which a fixed silvered-aluminium reflector 45 is located at the low-angle illuminated end 46 of the base portion 11 of the housing 10. The fixed reflector 45 is arranged and positioned to reflect to the receivers 18 incident low-angle solar radiation that enters the housing structure toward the end 46 and, depending upon the relative positions of the fixed reflector 45 and the receivers 18, the low-angle solar radiation may be reflected (in the longitudinal direction) to the receivers 18 either directly from the fixed reflector 45 or by re-reflection from the pivotal reflectors 30. Thus, the fixed reflector 45 functions effectively to increase the quantum of radiation reflected to the receivers 18 at the low-angle illuminated end 46 of the housing 10 and compensates for shadowing at the other end of the solar concentrator.

Variations and modifications may be made in respect of the embodiments of the invention as above described without departing from the scope of the appended claims.

1. A concentrator for solar radiation and which comprises:
a housing having an aperture arranged to admit incident solar radiation,
a plurality of laterally spaced linearly extending receivers located within the housing,
a plurality of linearly extending line focusing reflector elements associated with each one of the receivers and arranged to reflect toward the respective receivers incident solar radiation that enters the housing, each reflector element being preformed with a transverse concentrating profile from metal having a thickness within the range 0.05 mm to 2.00 mm and each reflector element being loaded in tension between longitudinally spaced coupling members, with longitudinally spaced end portions of each reflector element being connected to the respective coupling members in a manner to preserve the concentrating profile,
a drive mechanism arranged to impart pivotal drive to the reflector elements by way of the coupling members, and
a plurality of windows that are substantially transparent to solar radiation defining the aperture of the housing.

2. A concentrator as claimed in claim 1 wherein the housing includes a cover portion having three said windows that define the aperture of the housing, an upper window and opposite side windows arranged respectively in use of the concentrator to admit solar radiation from overhead and from easterly and westerly directions when the concentrator is orientated with the receivers extending in a north-south direction.

3. A concentrator as claimed in claim 3 wherein the respective side windows are inclined to form with the upper window an included angle within the range 105° to 165°.

4. A concentrator as claimed in claim 3 wherein the respective side windows are inclined to form with the upper window an included angle of about 150°.

5. A concentrator as claimed in claim 2 wherein the cover portion comprises a skeletal metal frame portion to which the windows are mounted.

6. A concentrator as claimed in claim 2 and comprising two said receivers, wherein each of the receivers is arranged to carry a heat exchange fluid which is heated in use of the concentrator by energy exchange from solar radiation.

7. A concentrator as claimed in claim 6 wherein the receivers are located within the cover portion of the housing and are mounted one to each of two parallel, spaced-apart linearly extending members of a skeletal metal frame to which the windows are mounted.

8. A concentrator as claimed in claim 7 wherein each receiver comprises a conduit which is located within a longitudinally extending channel portion of one of the linearly extending members of the skeletal metal frame.

9. A concentrator as claimed in claim 8 wherein a secondary reflector element is located adjacent each of the receivers and is arranged to reflect to the associated receiver radiation that impinges on the secondary reflector.

10. A concentrator as claimed in claim 9 wherein the secondary reflector is located within the channel portion of a said linearly extending member of the skeletal metal frame.

11. A concentrator as claimed in claim 10 wherein the secondary reflector is formed as a channel shaped element composed of two part-parabolic portions that interconnect along a central longitudinally extending cusp.

12. A concentrator as claimed in claim 1 and comprising two said receivers, wherein each of the receivers comprises a linear array of PV cells carried by a linearly extending carrier.

13. A concentrator as claimed in claim 12 wherein the receivers are located within a cover portion of the housing and are mounted one to each of two parallel, spaced-apart linearly extending members of a skeletal metal frame to which the windows are mounted.

14. A concentrator as claimed in claim 13 wherein each receiver includes a conduit which is located within a longitudinally extending channel portion of one of the linearly extending members of the skeletal metal frame, wherein the conduit is mounted in thermally conductive engagement with the linearly extending carrier and wherein the conduit is connectable to a source of coolant fluid.

15. A concentrator as claimed in claim 14 wherein a secondary reflector element is positioned adjacent each of the receivers and is arranged to reflect to the associated receiver radiation that impinges on the secondary reflector.

16. A concentrator as claimed in claim 1 wherein two groups of said reflector elements are located within the housing, one group being associated with each of the receivers and wherein each group of reflector elements is disposed too reflect upwardly toward the associated receiver incident solar radiation that enters the housing.

17. A concentrator as claimed in claim 16 wherein each group of reflector elements comprises between four and twelve individual reflector elements.

18. A concentrator as claimed in claim 1 wherein each reflector element has a thickness of the order of 0.3 mm.

19. A concentrator as claimed in claim 1 wherein each reflector element comprises a single-layer metal element that is formed with a generally circular transverse concentrating profile.

20. A concentrator as claimed in claim 1 wherein each reflector element is formed from aluminium having a silvered or anodised reflective surface.

21. A concentrator as claimed in claim 1 wherein each reflector element is subjected to a tensile loading within the range of 20 kg to 60 kg.

22. A concentrator as claimed in claim 1 wherein the longitudinally spaced end portions of each reflector element are connected to support structures within the housing by way of the longitudinally spaced coupling members through which pivotal drive is in use imparted to the reflector element from the drive mechanism.

23. A concentrator as claimed in claim 22 wherein the longitudinally spaced coupling members are mounted for rotation to the support structures.

24. A concentrator as claimed in claim 23 wherein the coupling members associated with at least one of the support structures are moveable axially with respect to the support structure(s) to apply tensile loading to the reflector elements.

25. A concentrator as claimed in claim 1 wherein each coupling member comprises two clamping components arranged to receive and clamp onto the end portion of the associated reflector element.

26. A concentrator as claimed in claim 25 wherein the clamping components are profiled to provide a clamping interface that matches the preformed concentrating profile of the associated reflector element.

27. A concentrator as claimed in claim 1 wherein the drive mechanism is arranged in use to impart pivotal drive to all of the coupling members at the opposite ends of the reflector elements.

28. A concentrator as claimed in claim 16 wherein the drive mechanism comprises a linear stepping motor and a linear actuator at each end of each group of reflector elements.

29. A concentrator as claimed in claim 28 wherein the linear stepping motor is arranged to effect translational motion of the linear actuator and, by way of the linear actuator, rotary motion of the coupling members.

30. A concentrator as claimed in claim 1 wherein the reflector elements associated with each receiver are formed with a radius of curvature that increases and a chordal width that decreases with increasing distance of the reflector elements from the receiver.

31. A concentrator as claimed in claim 1 and further comprising a reflector tracking system associated with each of the receivers, the reflector tracking system being arranged to detect for off-target movement of reflected radiation and to effect on-target restoration drive control of the reflector drive mechanism.

32. A concentrator as claimed in claim 31 wherein the reflector tracking system comprises temperature sensors located adjacent each end of each of the receivers.

33. A concentrator as claimed in claim 1 wherein fixed reflectors are located within the housing at opposite ends of the housing and are positioned to reflect to the receivers incident low-angle solar radiation that in use enters the housing.

34. A concentrator as claimed in claim 1 wherein a fixed reflector is located within the housing at a low-angle illuminated end of the housing and is positioned to reflect to the receivers incident low-angle solar radiation that in use enters the housing.
